(19) United States
(12) Patent Application Publication
(10) Pub. No.: US 2006/0239096 A1
(43) Pub. Date: Oct. 26, 2006

(54) Memory structure and memory refreshing method

(75) Inventors: Hsiu-Ming Chu, Taipei (TW); Kuang-Jui Ho, Taipei (TW); Ruei-Ling Lin, Taipei (TW)

Correspondence Address: MADSON & AUSTIN;GATEWAY TOWER WEST, SUITE 900, 15 WEST SOUTH TEMPLE, SALT LAKE CITY, UT, 84101, US

(73) Assignee: Via Technologies, Inc.

(21) Appl. No.: 11/408,141

(22) Filed: Apr. 20, 2006

(30) Foreign Application Priority Data
Apr. 22, 2005 (TW) 094113010

(51) Int. Cl. G11C 7/00

(52) U.S. Cl. 365/222

(57) ABSTRACT

The present invention relates to a memory-refreshing method applied to a computer system. The computer system includes a central processing unit (CPU), a north bridge chip in communication with the CPU and a system memory in communication with the north bridge chip. The system memory includes at least a first storage zone and a second storage zone. The first storage zone stores a specific data that remains refreshed when the CPU is in a first power-saving mode. The method comprising steps of: refreshing the first storage zone and the second storage zone respectively according to a first clock enable signal and a second clock enable signal generated by the north bridge chip when the CPU is in a normal operation mode; and remaining refreshing the first storage zone according to the first clock enable signal while suspending the second storage zone from being refreshed according to the second clock enable signal when the CPU is in the first power-saving mode

### FIELD OF THE INVENTION

The present invention relates to a memory structure and a memory-refreshing method therefor, and more particularly to a system memory structure of a computer system and a method for refreshing the system memory.

### BACKGROUND OF THE INVENTION

Current motherboard of a computer system basically consists of a central processing unit (CPU), a chipset and certain peripheral circuit. The CPU is core of the entire computer system, which dominates operation and cooperation among elements in the computer system, and performs logic operations as well. The chipset may include various combinations, and typically consists of a north bridge chip and a south bridge chip, wherein the north bridge chip communicates with high-speed buses while the south bridge chip communicates with low-speed ones in the motherboard.

Please refer to FIG. 1 which is a functional block diagram schematically illustrating the circuitry of a conventional motherboard. As shown, the motherboard 1 is a single CPU architecture, and comprises a chipset 2, which consists of the north bridge chip 20 and the south bridge chip 21. The north bridge chip 20 communicates with the CPU 10 via front side bus (FSB) 22. In addition, the north bridge chip 20 is coupled to the accelerated graphics port (AGP) interface 30 via AGP bus 301 and further coupled to random access memory (RAM) 31 via memory bus 311. The south bridge chip 21 is coupled to peripheral component interconnect (PCI) interface 40 via PCI bus 401, and further coupled to other low-speed devices such as industry standard architecture (ISA) interface 41, integrated drive electronics (IDE) interface 42, universal serial bus (USB) interface 43, keyboard 44 and mouse 45. Chipset 2 is a control center of the entire computer system and is in charge of communication between the CPU 10 and peripheral equipment, including access to RAM 31. North bridge chip 20 of chipset 2 coupled between CPU 10 and RAM 31 is the coordinating center for various signals or commands. Signals or commands to be read or executed in the computer system need to be processed by CPU 10 and temporarily stored in RAM 31 via the north bridge chip 20. Such memories include dynamic random access memory (DRAM), static random access memory (SRAM), dual in-line memory module (DIMM), synchronous DRAM (SDRAM), double data rate SDRAM (DDR SDRAM), DIMM SDRAM, etc.

Conventional display cards, graphics cards or graphics ports used in a computer system are designed following PCI protocol, and subsequently those complying with AGP protocol are developed so as to improve the displaying performance of the computer system. In general, AGP interface has better high-speed transmission efficiency than PCI interface. For example, it is preferred for 3D image processing, 3D graphing and texture mapping or some other application software.

When data access is performed via AGP interface, the system memory of the computer system as well as a built-in memory space specific to the AGP interface can serve as a frame buffer for the AGP interface. For example, as shown in FIG. 1, the AGP external graphics card 32 is mounted to the AGP interface 30 and has a built-in local memory 321. If the capacity of the local memory 321 is 4 MB and the graphics size to be processed is 10 MB, the system memory will support the extra 6 MB. The data access to the system memory (RAM 31) can be accomplished via AGP bus 301 and the north bridge chip 20. On the other hand, data access of any PCI external graphics card (not shown) mounted to PCI interface 40 is conducted to RAM 31 (i.e. system memory) via PCI bus 401, south bridge chip 21 and north bridge chip 20. The path is longer and the transmission efficiency would be decreased due to other PCI-interfaced I/O peripheral devices connected to PCI interface 40. Therefore, AGP interfacing has higher displaying speed and performance than PCI interfacing.

In addition to external graphics cards, internal graphics ports with graphics or image processing functions can also be built in a specific zone of the chipset or the north bridge chip, depending on hardware requirements of the computer system. Please refer to FIG. 2 which is a functional block diagram schematically illustrating the circuitry associated with a multi-functional north bridge chip in a computer system. The circuitry of FIG. 2 is similar to that of FIG. 1 except that the north bridge chip 20, AGP interface 30 and the AGP external display card 32 in FIG. 1 are replaced by a multi-functional north bridge chip 23 with internal graphics port 231. In contrast to external graphics cards, an internal graphics port in this prior art is built in the chipset or the north bridge chip of the computer system. Therefore, no additional external display card is required. On the other hand, due to the absence of the built-in memory, the only storage space available for data access of the internal graphics port 231 is the system memory (RAM 31). Therefore, internal graphics port 231 needs to share the system memory with other devices in the computer system. Such architecture may have some problems in general computer systems but is still preferable to portable computers that require compact device constitution and collocation and good integration. Nevertheless, memory management and power management are always important issues to all computer systems, particularly to portable computers.

### SUMMARY OF THE INVENTION

The present invention relates to a memory structure of a computer system, coupled to a north bridge chip of the computer system and comprising a plurality of the storage zones, wherein the storage zones are independently refreshed by the north bridge chip and independently suspended from being refreshed by the north bridge chip according to corresponding clock enable signals, and any of the storage zones, if suspended from being refreshed by the north bridge chip, is self-refreshed to maintain data stored therein.

In an embodiment, the clock enable signals are generated by the north bridge chip and transmitted to the storage zones via a memory bus.

In an embodiment, the storage zones are included in a system memory of the computer system, and the clock enable signals are asserted to refresh the storage zones respectively when a central processing unit (CPU) of the computer system is in a normal operation mode. At least one of the clock enable signals are suspended as corresponding storage zones are suspended from being refreshed by the north bridge chip when the CPU is in a power-saving mode.

In an embodiment, the memory structure further comprises a frame buffer disposed in a specific one of the storage zones for storing frame data to be displayed. The specific storage zone is kept refreshed and the other storage zones are suspended from being refreshed by the north bridge chip when the CPU is in a power-saving mode.

Preferably, each of the storage zones is in a smallest storage unit capable of maintaining integrity of data access by the north bridge chip.

The present invention also relates to a memory-refreshing method applied to a computer system. The computer system includes a central processing unit (CPU), a north bridge chip in communication with the CPU and a system memory in communication with the north bridge chip. The system memory includes at least a first storage zone and a second storage zone. The first storage zone stores a specific data that remains refreshed when the CPU is in a first power-saving mode. The method comprising steps of: refreshing the first storage zone and the second storage zone respectively according to a first clock enable signal and a second clock enable signal generated by the north bridge chip when the CPU is in a normal operation mode; and remaining refreshing the first storage zone according to the first clock enable signal while suspending the second storage zone from being refreshed according to the second clock enable signal when the CPU is in the first power-saving mode.

Preferably, the method further comprises a step of maintaining data of the second storage zone when the second storage zone is suspended from being refreshed according to the second clock enable signal. The data-maintaining can be self-refreshing.

In an embodiment, the refreshing of the second storage zone is suspended by suspending the second clock signal from the north bridge chip.

In an embodiment, the first storage zone includes a frame buffer, and the specific data is a frame data to be shown on a display device of the computer system.

In an embodiment, the CPU enters the power-saving mode after the computer system idles for more than a first preset standby time. Furthermore, the CPU enters a second power-saving mode after the computer system idles for more than a second preset standby time longer than the first preset standby time. The method further comprises a step of suspending the first storage zone from refreshing according to the first clock enable signal when the CPU is in the second power-saving mode.

### BRIEF DESCRIPTION OF THE DRAWINGS

The above contents of the present invention will become more readily apparent to those ordinarily skilled in the art after reviewing the following detailed description and accompanying drawings, in which:

FIG. 1 is a functional block diagram schematically illustrating the circuitry of a conventional motherboard;

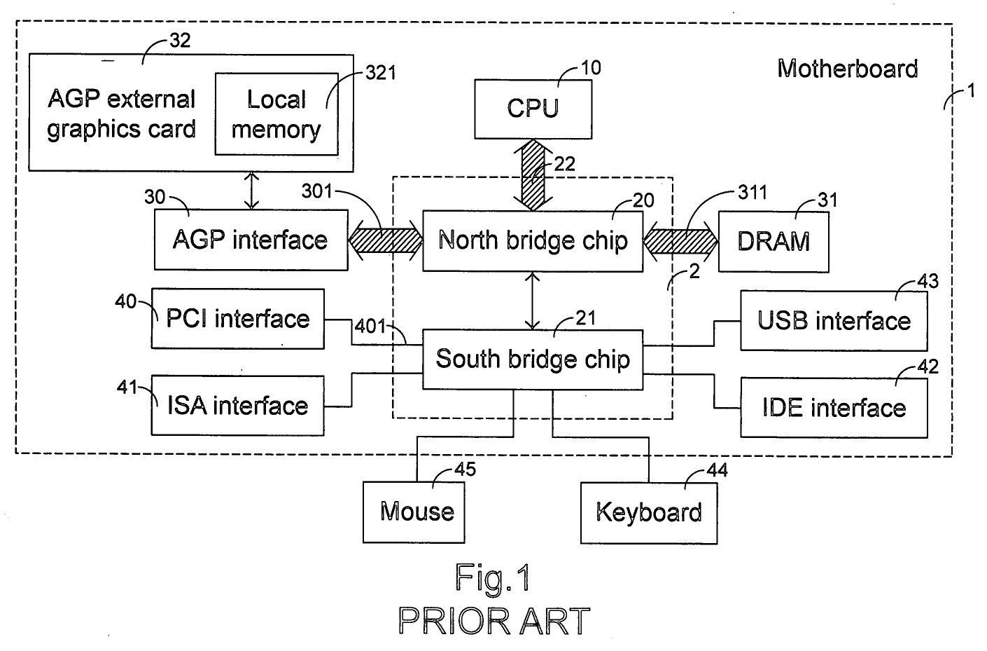

FIG. 2 is a functional block diagram schematically illustrating the circuitry of another conventional motherboard;

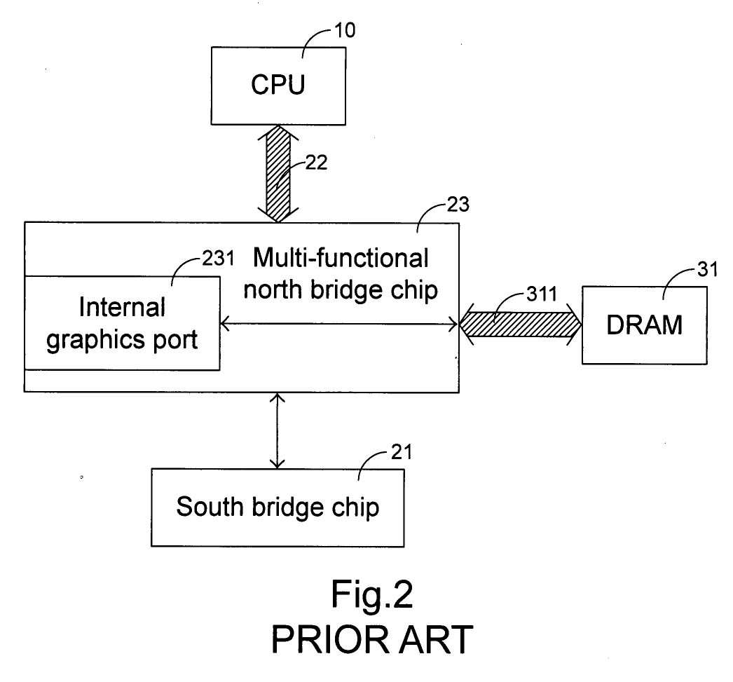

FIG. 3 is a functional block diagram schematically illustrating the circuitry of a motherboard according to an embodiment of the present invention; and

FIG. 4 is a flowchart illustrating a memory refreshing method according to the embodiment of FIG. 3.

### DETAILED DESCRIPTION OF THE PREFERRED EMBODIMENT

The present invention will now be described more specifically with reference to the following embodiments. It should be noted that the following descriptions of the preferred embodiments of this invention are presented herein for the purpose of illustration and description only; it is not intended to be exhaustive or to be limited to the precise form disclosed.

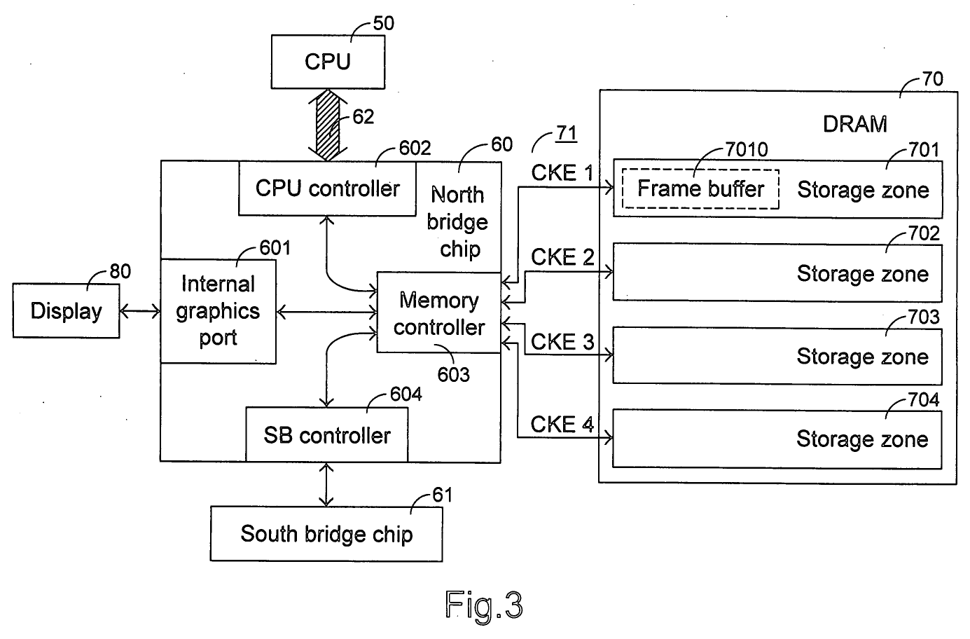

Please refer to FIG. 3. The computer system shown includes a CPU 50, a north bridge chip 60, a south bridge chip 61 and a system memory 70. The north bridge chip 60 is electrically connected to the CPU 50 and the system memory 70 respectively via front-side bus 62 and memory bus 71, and connected to the south bridge chip 61 directly. In this embodiment, the system memory 70 may be a DRAM. The south bridge chip 61 is coupled to low-speed devices (not shown). In this embodiment, internal graphics port 601 is built in the north bridge chip 60 for graphics processing and control. In addition, the north bridge chip 60 further comprises the CPU controller 602, the DRAM controller 603 and the south bridge chip (SB) controller 604 for processing and controlling signals associated with CPU 50, DRAM 70 and south bridge chip 61, respectively. The DRAM 70 is designed to include a plurality of storage zones, e.g. four storage zones 701, 702, 703 and 704. Each storage zone is defined by a rank, the smallest storage unit capable of maintaining integrity of data access according to the transmission specification of hardware. Also, each storage zone is controlled by a clock enable signal generated by the north bridge chip 60. The north bridge chip 60 can access the DRAM 70 via the memory bus 71 by the clock enable signals CKE 1, CKE 2, CKE 3 and CKE 4, respectively coupled to storage zones 701, 702, 703 and 704.

When the CPU 50 is in a normal operation mode, the north bridge chip 60 asserts the clock enable signals CKE 1, CKE 2, CKE 3 and CKE 4 to have the storage zones 701, 702, 703 and 704 constantly refreshed, respectively. For example, a frame data for displaying is recorded in the frame buffer 7010 of the storage zone 701. If the CPU 50 enters a power-saving mode, the north bridge chip 60 suspends assertion of the clock enable signals CKE2, CKE3 and CKE4 except CKE1 associated with the frame data in the frame buffer 7010. That is, the clock enable signals CKE 2, CKE 3 and CKE 4 are suspended while the storage zones 702, 703 and 704 are self-refreshed. Self-refreshing function is provided with an independent charging circuit disposed in DRAM in usual, which is capable of self-charging for a period of time. For a computer system requiring high power-saving efficiency, e.g. notebook computer or portable computer, it is a commonly seen technique.

When the frame data stored in frame buffer 7010 is to be shown on the display device 80 coupled to internal graphics port 601, the frame data needs to be performed with graphic computation and processing first by the internal graphics port 601, and then is transmitted to the display device 80 for displaying. Accordingly, the internal graphics port 601 utilizes the frame buffer 7010 in the storage zone 701 of DRAM 70 for data storage. The frame data then can be accessed for processing and computation from the frame buffer 7010. The frame buffer 7010 may occupy partial or the entire storage zone 701. In other words, to be compatible with the clock enabling signals, the storage zone 701 should be in the basic memory unit for data access, i.e. a rank. Since the frame data or image shown on display device 80 will be subject to change in a normal operation mode, the frame data stored in the frame buffer 7010 need to be constantly refreshed according to the clock enable signal CKE 1. The refreshing operation of a memory is implemented with the charging of a capacitor.

The above-mentioned power-saving mode, for example, can be managed according to ACPI (advanced configuration and power interface) protocol, which is developed and stipulated by several computer manufacturers and allows operating systems such as Windows® to manage power states of ACPI-compliant peripheral devices according to a specified algorithm. For example, if the computer system idles more than a preset standby time, the multi-level power management will involve in to adjust power consumption of various hardware devices, including CPU, hard disc, display device, memory, etc. According to ACPI protocol, the multi-level power management defines various pause phases of the CPU, including C2, C3, C4 and C5 states.

Further in the above embodiment of the present invention, if the CPU 50 enters C3 or higher power-saving state, in which no other device except the display device 80 accessing the DRAM 70 in the computer system, the north bridge chip 60 keeps assert only the clock enable signal CKE 1 to the storage zone 701 where the frame data is presented, but suspends assertion of other clock enable signals CKE 2, CKE 3 and CKE 4 so that the north bridge chip 60 does not have to refresh storage zones 702, 703 and 704. Instead, the storage zones 702, 703 and 704 are self-refreshed to maintain the data existed therein. In view of the self-refreshing technique, the DRAM 70 can have its own clock signal, so that there would be no data input/output cycle appearing on the bus to save the power consumption of generating external clock cycles. In addition to the storage zones 702, 703 and 704, the data refreshing of the CPU controller 602, the SB controller 604 and/or various I/O peripheral devices coupled to the SB controller 604 will also be temporarily powered down. Thus power consumption of un-function devices can be saved.

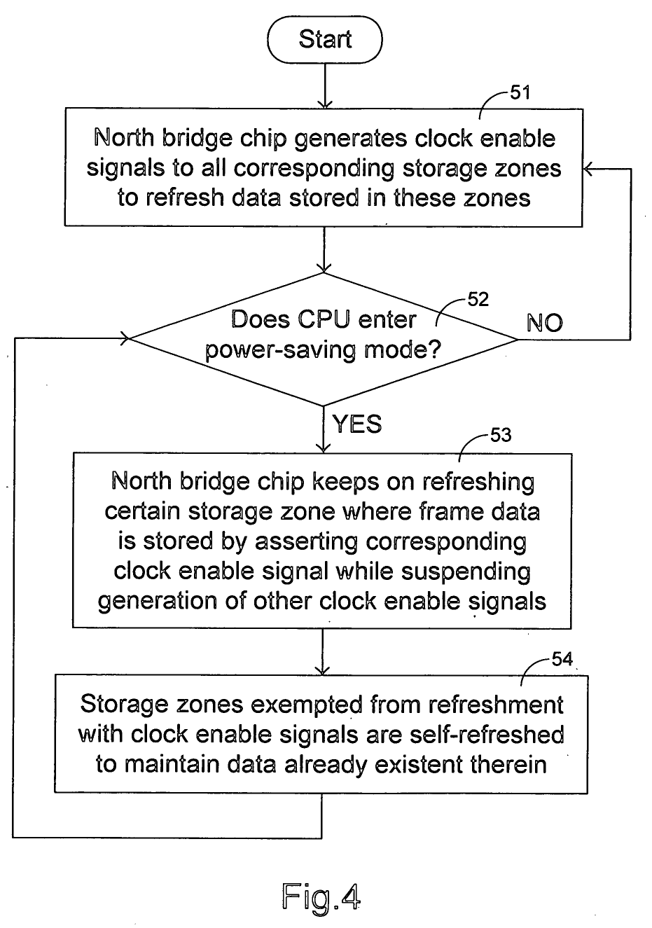

Therefore, it can be observed that in the present memory structure, the storage zones are independently refreshed by the north bridge chip and independently suspended from being refreshed by the north bridge chip according to corresponding clock enable signals. Preferably, any of the storage zones, if suspended from being refreshed by the north bridge chip, is self-refreshed to maintain data stored therein. The memory refreshing method of the present invention is summarized in the flowchart of FIG. 4. First of all, if the CPU 50 is in a normal operation mode, north bridge chip 60 will generate four clock enable signals CKE 1, CKE 2, CKE 3 and CKE 4 to the storage zones 701, 702, 703 and 704 of DRAM 70, respectively, for refreshing data stored in these zones (Step 51). When the CPU 50 enters a power-saving mode (Step 52), the north bridge chip 60 keeps refreshing the storage zone 701 where the frame data is stored by providing the clock enable signal CKE 1 while suspending other clock enable signals CKE 2, CKE 3 and CKE 4 to other storage zones 702˜704(Step 53). Meanwhile, the storage zones 702, 703 and 704 are self-refreshed to maintain data existent therein (Step 54). For ones skilled in the art, the self-refreshing mechanism can be replaced by any other suitable data-maintaining mechanism.

Although the internal graphics port 601, the memory controller 603 and the storage zone 701 stay fully powered on in the above embodiment for displaying the frame data on display device 80, they might also be powered down once the idle state lasting for even longer such that the frame data shown on the display device 80 may not need to be refreshed temporarily. Under this circumstance, the storage zone 701 is not refreshed by the north bridge chip 60 and the clock enable signal CKE 1, but keeps self-refreshed to maintain data already existent. The self-refreshing mechanism allows the system to successfully and correctly recover from the power-saving mode.

The feature of the present invention has been described with an exemplified application of an internal graphics port. Nevertheless, the present invention can also be applied to an external graphics card, either PCI or AGP graphics cards. Since in addition to the system memory, a local memory is also available for data storage in the presence of an external graphics card, it is necessary to locate the frame buffer where data refresh is required before entering the power-saving mode.

While the present invention has been described in terms of what is presently considered to be the most practical and preferred embodiments, it is to be understood that the present invention needs not be limited to the disclosed embodiment. On the contrary, it is intended to cover various modifications and similar arrangements included within the spirit and scope of the appended claims that are to be accorded with the broadest interpretation so as to encompass all such modifications and similar structures.

What is claimed is:

1. A memory structure of a computer system, coupled to a north bridge chip of said computer system and comprising a plurality of storage zones, wherein said storage zones are independently refreshed by said north bridge chip and independently suspended from being refreshed by said north bridge chip according to a plurality of corresponding clock enable signals, and any of said storage zones, if suspending from being refreshed by said north bridge chip, is self-refreshed to maintain data stored therein.

2. The memory structure according to claim 1, wherein said clock enable signals are generated by said north bridge chip and transmitted to said storage zones via a memory bus.

3. The memory structure according to claim 1, wherein said storage zones are included in a system memory of said computer system, and said clock enable signals are asserted to refresh said storage zones respectively when a central processing unit (CPU) of said computer system is in a normal operation mode.

4. The memory structure according to claim 1, wherein said storage zones are included in a system memory of said computer system, and at least one of said clock enable signals is suspended so that at least one of said storage zones is suspended from being refreshed by said north bridge chip when said central processing unit (CPU) of said computer system is in a power-saving mode.

5. The memory structure according to claim 1, further comprising a frame buffer disposed in a specific one of said storage zones for storing frame data to be displayed.

6. The memory structure according to claim 5, wherein said storage zones are included in said system memory of said computer system, and said specific storage zone is kept refreshed and others of said storage zones are suspended from being refreshed by said north bridge chip when said central processing unit (CPU) of said computer system is in a power-saving mode.

7. The memory structure according to claim 1, wherein each of said storage zones is in a smallest storage unit capable of maintaining integrity of data access by said north bridge chip.

8. A memory-refreshing method for a computer system, said computer system comprising a central processing unit (CPU), a north bridge chip in communication with said CPU and a system memory in communication with said north bridge chip, said system memory comprising at least a first storage zone and a second storage zone, said first storage zone storing therein a specific data remaining refreshed when the CPU is in a first power-saving mode, the method comprising steps of:
refreshing said first storage zone and said second storage zone according to a first clock enable signal and a second clock enable signal generated by said north bridge chip when said CPU is in a normal operation mode; and
remaining refreshing said first storage zone according to said first clock enable signal while suspending said second storage zone from refreshing according to said second clock enable signal when said CPU is in said first power-saving mode.

9. The method according to claim 8, further comprising a step of maintaining data of said second storage zone when said second storage zone is suspended from being refreshed by said north bridge chip according to said second clock enable signal.

10. The method according to claim 9, wherein maintaining data of said second storage zone is implemented by self-refreshing.

11. The method according to claim 8, wherein refreshing of said second storage zone is suspended by suspending said second clock signal by said north bridge chip.

12. The method according to claim 8, wherein said first storage zone comprises a frame buffer, and said specific data is a frame data to be shown on a display device of said computer system.

13. The method according to claim 8, wherein said CPU enters said power-saving mode after said computer system idles for more than a first preset standby time.

14. The method according to claim 13, wherein said CPU enters a second power-saving mode after said computer system idles for more than a second preset standby time longer than said first preset standby time.

15. The method according to claim 14, further comprising a step of suspending said first storage zone from refreshing by said north bridge chip according to said first clock enable signal when said CPU is in said second power-saving mode.
